(19) United States
(12) Patent Application Publication
(10) Pub. No.: US 2011/0256377 A1
(43) Pub. Date: Oct. 20, 2011

(54) PHOTOVOLTAIC STRUCTURES PRODUCED WITH SILICON RIBBONS

(76) Inventors: Shivkumar Chiruvolu, San Jose, CA (US); Neeraj Pakala, Cupertino, CA (US); Scott Ferguson, Pleasanton, CA (US); Kieran Drain, Newhall, CA (US)

(21) Appl. No.: 12/948,019

(22) Filed: Nov. 17, 2010

Related U.S. Application Data
(60) Provisional application No. 61/262,273, filed on Nov. 18, 2009.

(51) Int. Cl. B32B 9/00; H01L 21/225; B32B 37/00; B05C 5/00; C23C 16/00; H01L 21/31; B05B 13/02

(52) U.S. Cl. 428/220; 438/778; 438/558; 118/324; 118/316; 118/718; 156/324; 257/E21.24; 257/E21.145

(57) ABSTRACT

Photovoltaic elements can be formed by in-motion processing of a silicon ribbon. In some embodiments, only a single surface of a silicon ribbon is processed in-motion. In other embodiments both surfaces of a silicon ribbon is processed in-motion. In-motion processing can include, but is not limited to, formation of patterned or uniform doped regions within or along the silicon ribbon as well as the formation of patterned or uniform dielectric layers and/or electrically conductive elements on the silicon ribbon. After performing in-motion processing, additional processing steps can be performed after the ribbon is cut into portions. Furthermore, post-cut processing can include, but is not limited to, the formation of solar cells, photovoltaic modules, and solar panels.

### CROSS REFERENCE TO RELATED APPLICATIONS

This application claims priority to copending U.S. provisional patent application Ser. No. 61/262,273 filed Nov. 18, 2009 to Chiruvolu et al., entitled “Photovoltaic Structures Assembled form Silicon Ribbons,” incorporated herein by reference.

### FIELD OF THE INVENTION

The invention relates to photovoltaic devices comprising sheets of elemental silicon as the light receiving material that generates a photocurrent with doped structures used for harvesting the photocurrent. The invention further relates to methods for directly processing silicon ribbons as the ribbons are being generated to form structures relevant for the photovoltaic element.

### BACKGROUND OF THE INVENTION

Photovoltaic cells operate through the absorption of light to form electron-hole pairs. A semiconductor material can be conveniently used to absorb the light with a resulting charge separation. The photocurrent is harvested at a voltage differential to perform useful work in an external circuit, either directly or following storage with an appropriate energy storage device.

Various technologies are available for the formation of photovoltaic cells, e.g., solar cells, in which a semiconducting material functions as a photoconductor. A majority of commercial photovoltaic cells are based on silicon semiconductor. With non-renewable energy sources continuing to be less desirable due to environmental and cost concerns, there is continuing interest in alternative energy sources, especially renewable energy sources. Increased commercialization of renewable energy sources relies on increasing cost effectiveness through lower costs per energy unit, which can be achieved through improved efficiency of the energy source and/or through cost reduction for materials and processing.

### SUMMARY OF THE INVENTION

In one aspect, the invention pertains to a silicon ribbon processing apparatus. The silicon ribbon processing apparatus comprises a silicon ribbon production system, a deposition unit and a silicon ribbon handling system. The silicon ribbon production system generally comprises a crucible for holding a quantity of molten silicon and strings passing through the crucible to pull a silicon ribbon from the surface of molten silicon within the crucible. The deposition unit comprises a deposition element positioned to deposit a quantity of composition onto a moving silicon ribbon pulled from the silicon ribbon production system and a quantity of a composition to be deposited onto a surface of the silicon ribbon. Also, the silicon ribbon handling system generally comprises conveying elements positioned to control the movement of the silicon ribbon from the silicon ribbon production unit past the deposition unit.

In some embodiments, the deposition unit comprises a reservoir holding a dopant source and a nozzle for the delivery of the dopant source. In one embodiment the dopant source comprises a silicon particle ink. In some embodiments the deposition unit comprises a p-dopant source, an n-dopant source, a first nozzle to deliver the p-dopant to a first side of the silicon ribbon and a second nozzle to deliver n-dopant to a second side opposite the first side of the silicon ribbon. In some embodiments the deposition unit comprises a p-dopant source and an n-dopant source and nozzles configured to pattern the p-dopant and the n-dopant along the same side of silicon ribbon. In some embodiments the deposition unit comprises a CVD system connected to precursor reservoirs for the deposition of an inorganic dielectric material. In one embodiment the CVD system comprises a silane source and an ammonia source such that the CVD system deposits a layer of silicon nitride. In one embodiment the silicon ribbon production apparatus further comprises a polymer sheet dispenser and lamination system configured for laminating the polymer sheet over the inorganic dielectric material. In some embodiments the deposition unit comprises a source for elemental metal deposition.

In a second aspect, the invention pertains to a method for the formation of a passivation layer on a silicon sheet. The method comprises depositing a dielectric material or a dielectric precursor material onto a moving silicon ribbon having an average width from about 1 cm to about 30 cm, an average thickness from about 60 microns to about 750 microns, the silicon ribbon having a temperature from about 600° C. to about 1200° C. In some embodiments the dielectric material or the dielectric precursor material comprises a dielectric precursor material comprising a spin-on glass. In some embodiments the dielectric material or the dielectric precursor material comprises a dielectric material and wherein the depositing comprises a CVD process wherein the precursor compositions are directed through a nozzle toward the silicon ribbon. In some embodiments the silicon ribbon is moving at a rate from about 0.1 centimeters per minute (cm/min) to about 50 cm/min.

In a third aspect, the invention pertains to a method for forming a highly doped surface layer on a silicon sheet. The method comprises depositing a first dopant material comprising doped silicon particles or a dopant source precursor onto a surface of a moving silicon ribbon to form a first coated surface, the silicon ribbon having an average width from about 1 cm to about 30 cm, an average thickness from about 60 microns to about 750 microns, to form a dopant coating; and curing the dopant coating to form a highly doped silicon surface layer. In some embodiments the first dopant material comprises doped silicon particles and wherein the curing comprises passing a heated roller over the coated surface. In some embodiments, the first dopant material comprises a doped spin-on glass and wherein the curing comprises irradiation with a heat lamp. In some embodiments the first coated surface comprises a p-type dopant element and the method for forming a highly doped surface layer on a silicon sheet further comprises depositing a second dopant material to form a second coated surface on the silicon ribbon opposite the first coated surface, wherein the second dopant material comprises a n-type dopant. In one embodiments, the method for forming a highly doped surface layer on a silicon sheet further comprises depositing a second dopant material such that the first coated material and the second coated material form a selected pattern on the first coated surface.

In a fourth aspect, the invention pertains to a method for forming a protective polymer layer on a silicon sheet. The method comprises laminating a polymer sheet onto a moving front surface of a silicon ribbon an average width from about 1 cm to about 30 cm, an average thickness from about 60 microns to about 750 microns. In some embodiments the polymer sheet comprises polycarbonate. In some embodiments the laminating step comprises passing the polymer sheet and silicon ribbon together through rollers.

In a fifth aspect, the invention pertains to a ribbon material. In some embodiments, the ribbon material comprises a doped silicon ribbon and an inorganic dielectric coating on a surface of the silicon ribbon, the ribbon material having a length of at least about 15 meters, an average width from about 1 cm to about 30 cm, an average thickness from about 60 microns to about 750 microns and a dopant concentration from about 1.0×10¹⁸ to about 5×10²⁰ dopant atoms per cubic centimeter and the inorganic dielectric coating having an average thickness from about 10 nm to 800 nm. In some embodiments the ribbon material has a length of at least about 25 meters and is wound on a spool.

### BRIEF DESCRIPTION OF THE FIGURES

FIG. 1 is a front view of a photovoltaic cell with doped contacts along both the front and rear surfaces in which a current collector along a grid is shown.

FIG. 2 is a sectional side view of the photovoltaic cell of FIG. 1 taken along line 2-2.

FIG. 3 is a back view of a photovoltaic cell with back contacts of opposite polarity without any back sealing material blocking the view of the cell.

FIG. 4 is a sectional side view of the photovoltaic cell of FIG. 3 taken along line 4-4.

FIG. 5 is a fragmentary perspective view of a silicon ribbon production system in which the crucible within the enclosure is shown and other hidden structure within the enclosure is shown in phantom lines.

FIG. 6A is a schematic perspective view of a silicon ribbon processing apparatus in which a portion of the processing is performed on a silicon ribbon prior to cutting the ribbon into portions of ribbon silicon and a portion of the processing is performed on the cut ribbon silicon.

FIG. 6B is schematic side view of a portion of a silicon ribbon processing apparatus in which in-motion processing is performed on horizontal sections of both sides of the ribbon.

FIG. 7 is a fragmentary perspective view of processed silicon ribbon being placed on a spool.

FIG. 8 is a schematic side view of an in-motion processing section for processing silicon ribbon for the formation of photovoltaic cells having doped contacts on both surfaces of cell

FIG. 9 is a perspective view of slit nozzles oriented to deposit a line of coating material onto two sides of a ribbon scanned between the respective nozzle elements.

FIG. 10 is a front view of an array of circular nozzles.

FIG. 11 is a schematic side view of an embodiment of an in-motion processing section designed to process one side of a silicon ribbon as the front surface of back contact photovoltaic cells with a polymer sheet cover following cutting of the ribbon into individual cells.

FIG. 12 is a schematic side view of an embodiment of an in-motion processing section designed to process both sides of a silicon ribbon for the formation of structures of a back contact photovoltaic cell.

FIG. 13 is a schematic back plan view of a photovoltaic module with four cells formed from silicon ribbon connected in series.

### DETAILED DESCRIPTION OF THE INVENTION

As described herein, efficient manufacturing of solar cells and modules can be accomplished using silicon ribbons for a silicon semiconductor core of the cells. Silicon ribbons provide a cost effective source of silicon that can be produced with good qualities. Silicon ribbons are polycrystalline silicon sheets pulled from a molten silicon reservoir. Production techniques have been refined such that the silicon can be produced with relatively large crystallite size, such that the resulting solar cells can exhibit good efficiencies. Processes with some processing steps and/or stabilization of the silicon while the ribbon remains on the move from initial formation can simplify the overall process and facilitate formation of lower cost photovoltaic cells. In some embodiments, low temperature process steps can be used to form the solar cells for corresponding energy savings during cell production. In additional or alternative embodiments, processing steps can be performed on the ribbon retaining significant amounts of heat from formation that can be used to facilitate the processing steps. Due to the thinness of the silicon ribbons, the formation of photovoltaic structures with the silicon ribbons can provide for reduced use of silicon resources relative to some wafer based photovoltaic cells. Appropriate in-motion processing steps can be adapted for formation of photovoltaic cells with front and back contacts or with only back contacts. In some embodiments, flexible solar cells can be produced that can provide applications in a broader range of contexts.

Photovoltaic modules generally comprise a transparent front sheet that is exposed to light, generally sunlight, during use of the module. Within the photovoltaic module, one or more solar cells, i.e., photovoltaic cells, can be placed adjacent to the transparent front sheet such that light transmitted through the transparent front sheet can be absorbed by a semiconductor material in the photovoltaic cell. The transparent front sheet can provide support, physical protection as well as protection from environmental contaminants and the like. In the photovoltaic cells described herein, the semiconductor active material comprises elemental silicon, which is generally formed as a silicon ribbon from a silicon melt. With a photovoltaic cell, following absorption of light, photocurrent can be harvested to perform useful work through connection to an external circuit. For a photovoltaic cell, improved performance can be related to increased energy conversion efficiency for a given light fluence and/or to lowering the cost of producing a cell. The cells described herein generally are designed for at least moderate conversion efficiency with low cost production.

The bulk semiconductor can be lightly doped to increase electron mobilities of the semiconductor material. Also, regions with increased dopant concentrations, doped contacts, interfacing with the semiconductor material facilitate the harvesting of the photocurrent. In particular, electrons and holes can segregate to the respective n-doped and p-doped regions. The doped contact regions interface with electrical conductors that form current collectors to harvest the photocurrent formed by absorbing light to generate a potential between the two poles of the contacts. Within a single cell, the doped contact regions of like polarity can be connected to a common current collector such that the two current collectors associated with the different polarity of doped contacts form the counter electrodes of the photovoltaic cell.

In the following, embodiments of photovoltaic cells and processes can be based on polycrystalline silicon, which is formed as a semiconductor ribbon. A significant feature of the silicon ribbons formed from a drawing process, such as with string stabilization, is that the ribbon is generated in motion. Specifically, the ribbon is drawn from a volume of molten silicon. Apparatuses and corresponding methods have been developed to provide for replenishment of the silicon melt and general improvements to the ribbon production approaches. The ribbon production technique can be performed while producing good quality silicon having moderately large crystallite sizes. The in-motion aspect of the ribbon production can be exploited for the design of lower cost processing techniques to form a photovoltaic structure from the ribbon. For example, some processing steps can be performed on the moving ribbon very efficiently to reduce the processing after cutting the ribbon. Then, for particular embodiments, additional process steps can be performed after cutting a selected length of ribbon silicon.

Ribbons of polycrystalline silicon have been formed from molten silicon. In general, the ribbons are grown from a structure pulled from the silicon melt. For example, the silicon ribbon can be grown between two strings as described in U.S. Pat. No. 4,594,229 to Ciszek et al., entitled “Apparatus for Melt Growth of Crystalline Semiconductor Sheets,” incorporated herein by reference. Growth of a crystalline ribbon from a seed ribbon is described further in U.S. Pat. No. 4,469,552 to Thornhill, entitled “Process and Apparatus for Growing a Crystal Ribbon,” incorporated herein by reference. An improved apparatus to implement the Ciszek process using replenishment of the molten silicon and continuous feeding of string for the edges is described in U.S. Pat. No. 4,627,887 to Sachs, entitled “Melt Dumping in String Stabilized Ribbon Growth,” incorporated herein by reference. Alternative approaches for replenishing the material of the silicon melt have been described, for example, in U.S. Pat. No. 6,090,199 to Wallace et al., entitled “Continuous Melt Replenishment for Crystal Growth,” and in U.S. Pat. No. 7,344,594 to Holder, entitled “Melter Assembly and Method for Charging a Crystal Forming Apparatus With Molten Source Material,” both of which are incorporated herein by reference.

Generally, silicon ribbons have an average thickness from about 75 microns to about 1 millimeter and a width from about 10 millimeters to about 100 millimeters. The silicon can have a low doping concentration, such as of an n-type dopant or a p-type dopant, to increase the electron mobility of the silicon. The parameters of the ribbon structure can be adjusted by the melt pull process. While the ribbons are polycrystalline, the ribbons can have crystallite sizes on the order of centimeters. With relatively large crystallite sizes, the silicon can exhibit a high minority carrier lifetime, and high efficiency solar cells can be achieved. Specifically, efficiencies of 17.8% have been reported from solar cells formed form silicon ribbons. See, an article by Kim et al., entitled “String Ribbon Silicon Solar Cells With 17.8% Efficiency,” 3rd World Conference on Photovoltaic Energy Conversion, Osaka, Japan, May 11-18, 2003. Thus, silicon ribbons provide a desirable material for solar cell formation.

In general, the silicon ribbons can be incorporated into the formation of any desired solar cell structure. For example, the ribbons can be used for the formation of a solar cell structure with front and back contacts. To form such a structure, opposite dopants are applied to the front and back surface of the solar cell. The delivery of dopants is described further below. A passivation layer can then be applied over each surface. Electrical contacts can be applied to each surface to provide for harvesting the photocurrent. The front surface current collector can be patterned to provide for the transmission of light through to the silicon semiconductor material or a transparent conductive electrode can be applied.

In some embodiments, silicon ribbons can be conveniently used for the formation of back contact solar cells in which contacts of both polarities are placed along the back of the solar cell where the front surface is the light receiving surface. Several techniques have been developed for the effective delivery of dopants in a pattern to the back surface of a silicon foil. The patterning of dopants can be performed in-motion using appropriate deposition techniques or on a section of silicon ribbon that is cut from the continuous ribbon for further processing. The current collectors are correspondingly patterned according to the pattern of the doped contacts. For either configuration of cell, holes are generally placed through a dielectric layer to provide electrical connectivity between a respective current collector and a doped contact.

Desirable processing approaches for silicon ribbons can involve in-motion processing that has the potential of reducing processing costs to form potentially lower cost solar cells for suitable applications. Specifically, in-motion processing steps can comprise deposition of materials, modification of materials along the surface of the silicon ribbon and/or lamination of a protective coating such as a polymer sheet to the ribbon. Deposition of materials can be directed to deposition of a dopant source material, a passivation material and/or an electrically conductive material for current collection. In motion processing can involve, for example, delivery of heat, radiation and/or pressure to modify the materials at the surface, such as the deposited materials. After performing a selected number of in-motion processing steps, additional steps can be performed after the ribbon is cut into portions. With the portions of ribbon, one or both surfaces can be subjected to additional processing steps to complete the photovoltaic cell.

The processing apparatus generally comprises a silicon ribbon production device, and at least the in-motion components are constructed around the silicon ribbon production device since the silicon ribbon while in-motion is a continuous structure. The production of the silicon ribbon results in a ribbon motion that is fixed to provide desired ribbon properties, and the remaining in-motion processing is adapted to accommodate this motion. The ribbon production apparatus generally is within an enclosure to have an oxygen depleted atmosphere during ribbon production. One or more in-motion processing stations can also be within the enclosure. The enclosure can be thermally insulating to help retain heat within the silicon ribbon, and the enclosure can optionally include heating to control the ribbon temperature.

Some care in handling the silicon ribbons is appropriate, but reasonable handling with rollers and the like can be used to guide the movement of the silicon ribbons. Suitable rollers can include, for example, rollers formed from ceramic materials, such as alumina, quartz or the like such that the rollers can tolerate the high heat without damage. If the ribbons have sufficiently cooled, metal rollers can be used, such as stainless steel rollers with a polymer coating. In general, the rollers should be smooth, although a textured roller can be used to apply texture.

The front surface of the solar cell can be made textured to scatter light entering the photovoltaic cell to increase light absorption. The texture can be introduced by the deposition of the passivation layer, through the lamination of the polymer sheet, with a textured roller that mechanically introduces texture onto the surface or a combination thereof. Texture can also be applied using a KOH etch. For example, a KOH solution can be sprayed onto the surface for a selected period of time or the ribbon can be contacted with a KOH solution bath. In general, any desired texture can be applied, such as a regular angled shaped texture, although some texturing techniques may generally introduce a more random type of texture.

The deposition of dopant elements can comprise the deposition of a suitable liquid comprising a dopant element, which can comprise, for example, an inorganic acid, a doped spin-on glass composition, doped silicon particles in an ink or doped silicon particles in an ink. Using these liquids, p-type dopants or n-type dopants can be delivered into the surface of the silicon ribbon. The dopant liquid can be distributed over the entire surface, such as for the formation of contacts on the front and back surfaces, or the doped particles can be patterned to place opposite dopants (n-type and p-type) at different locations along the back surface of the cell. The dopant liquid or ink can be applied along a surface, for example, using spray coating, dip coating, or the like. Patterned coatings can be formed, for example, using ink jet printing or other suitable patterning deposition technique.

The dopant liquid generally is processed to drive dopant elements into the silicon material from the dopant liquid. Suitable processes to drive the dopant into the silicon material can comprise the application of heat, and the delivery of the dopant onto a hot silicon ribbon near the production point of the ribbon can significant facilitate the dopant drive-in process. In other words, the dopants can be sprayed onto the surface and the heat of the silicon ribbon and/or addition of heat can be used to drive the dopant into the surface of the silicon.

Generally, each surface of the silicon ribbon can also comprise a dielectric layer, which is applied as a passivation layer over doped contacts, whether or not patterned, or over a front surface without doped contacts. In general, dielectric layers can be formed using any reasonable processing approach. It can be desirable to deposit a passivation layer onto one or both surfaces of the silicon ribbon in-motion. If the passivation layer or a corresponding precursor material is sprayed onto the silicon foil close to the melt, the heat of the silicon can be used to further drive the formation of the passivation layer.

With respect to passivation layers, thin layers of an inorganic dielectric with good adherence to the semiconductor layer can provide the passivation. The passivation layer protects the semiconductor layer and generally is formed of a dielectric material that forms an electrically insulating layer along the surface. These passivation layers can protect the semiconductor material from environmental degradation and reduce surface recombination of holes and electrons. In particular, suitable passivation layers can comprise, for example, metal oxides, metal nitrides, metal oxynitrides, metal carbides and the like. Specifically, passivation layers can comprise, for example, SiNₓO_{y}, x≦4/3 and y≦2, silicon oxide (SiO₂), silicon nitride (Si₃N₄), silicon rich oxide (SiOₓ, x<2), silicon rich nitride (SiNₓ, x<4/3), aluminum oxide, aluminum nitride, or the like, or combinations thereof.

Inorganic dielectrics for passivation layers can be applied in motion through various processes. Suitable processes can be based on formation of the dielectric material during the deposition process. For example, a spin-on-glass material or sol-gel precursor materials can be sprayed on the moving silicon material. The heat from the silicon as well as any added heat can cure the spin on glass into the desired dielectric material. In alternative or additional embodiments, an oxide dielectric layer, e.g., silicon oxide or aluminum oxide, can be deposited with an atmospheric pressure CVD system or a scanning subatmospheric pressure CVD system integrated with the ribbon production apparatus.

In some embodiments, it is desirable to deposit a dielectric layer using in-line processing. For example, a dielectric layer can be deposited on a surface as the silicon ribbon is being transported as a continuous web. An inorganic dielectric layer, such as silicon oxide, silicon nitride, silicon carbide, silicon oxynitride, aluminum oxide or the like, can be deposited, for example, using a plasma spray or various in-line CVD processes described further below. In additional or alternative embodiments, an organic polymer dielectric can be applied over a thin inorganic passivation layer using spray coating, dip coating, extrusion coating lamination of a polymer web or other appropriate coating approach, and if the polymer dielectric is applied with a solvent, the solvent can be removed through evaporation. Suitable polymer dielectrics can comprise organic polymers, such as polycarbonates, vinyl polymers, fluorinated polymers, such as polytetrafluoroethylene, polyamides, EVA or the like. The polymer can provide desirable electrical insulation properties.

Current collectors can be appropriately formed in-motion if desired. If a current collector is placed along the front surface of the photovoltaic cell, the front current collector should provide for the transmission of a significant fraction of the incident light. For example, the front current collector can be a transparent conductive oxide, such as indium tin oxide, that can be deposited with an appropriate in-motion CVD technique. Alternatively, a front current collector can comprise a pattern of electrically conductive metal in which the pattern is selected to keep most of the front surface free of metal to provide for transmission of light. A patterned metal current collector can be formed, for example, by printing a metal ink onto the front surface and curing the ink into a continuous electrically conductive structure. For the back current collector, a simple reflective metal conductive layer can be applied, for example, with physical vapor deposition, if the current collector of opposite polarity is on the front side of the cell. If both sets of doped contacts are along the back surface, the current collectors of each polarity can be appropriately patterned, for example, with a silver ink or the like.

It can be desirable to laminate a polymer sheet onto the front surface of the silicon ribbon, which can be performed if the processing of the front surface is completed in motion. The lamination with the polymer sheet provides protection for the front surface during additional processing, and may or may not serve as the exclusive front surface protective coating for the photovoltaic cell during use. With the front surface stabilized, the further processing to complete the cell can be performed on the back of the cell with simplified handling based on focusing on structure formation on the back surface. With respect to protection of the front surface, the photovoltaic cell may or may not be placed with the polymer sheet against a glass cover. If the polymer sheet forms the protective outer layer for the photovoltaic cell, the cell can be moderately flexible since the semiconductor sheet itself can be flexible.

Some of the processing steps can be performed after cutting the ribbon into portions, such as a portion selected for the formation of an individual cell. Several alternative processes for the formation of doped contacts for photovoltaic devices have been developed for the effective placement in a selected pattern to form a back contact solar cell, and these techniques can be effectively adapted for silicon ribbon structures either before or after cutting of the silicon ribbon. For back contact cells, it can be desirable to process at least the front side in-motion through to the lamination of a polymer sheet over a passivation layer to reduce or eliminate turning the cut portion of silicon ribbon over for additional processing. If desired, the laminated polymer-silicon ribbon can be wound onto a roll for later use, or the laminate can be used directly for assembly into a solar cell module. In general, the silicon ribbon has a limit on a radius of curvature that avoids a significant risk of cracking the ribbon, and this feature of the ribbon can be incorporated into the design of the apparatus. A plurality of rollers can be used to effectuate a change of direction of the movement of the ribbon to reduce strain.

In some embodiments, the front surface of the ribbon can be laminated to the transparent substrate with the silicon ribbon still in the form of a continuous web. Once a desired length of silicon ribbon is secured to the transparent substrate, the silicon ribbon can be cut, and the free edge of the web of the silicon ribbon can be secured to a subsequent transparent substrate. In some embodiments, the silicon ribbon can be cut prior to lamination to the transparent substrate. An adhesive, heat bonding or the like can be used to secure the silicon ribbon to a substrate. To form a solar cell module, it can be desirable to secure the front surface of a cut portion of silicon ribbon with or without a polymer web to a transparent glass substrate, for example, an inorganic glass, such as a silica glass.

The in-motion processing approaches described herein are well suited for the processing of silicon ribbons, which are produced in motion. The heat from the initially formed silicon ribbon can be advantageously used to facilitate further processing steps to reduce overall energy consumption and to reduce overall processing time. In general, the in-motion processing steps can make efficient use of materials, and the silicon ribbons provide good quality silicon in a relatively thin format. Overall, the in-motion processing approach based off of silicon ribbon provides and efficient and effective approach for producing at least moderate efficiency or high efficiency photovoltaic cells.

### Photovoltaic Cell Structure

A photovoltaic cell can be formed with a portion of a silicon ribbon as the semiconducting core. The front surface is processed to provide for light to strike the front surface of the semiconductor ribbon and suitable contacts are supplied to harvest the photocurrent. As noted above, in general, the photovoltaic cells can be formed with either both front and back contacts or with only back contacts. The front surface comprises a transparent protective layer that may or may not provide for a flexible photovoltaic cell. The cell can be sealed for protection of the cell with appropriate electrical connections available for connection with an outside circuit. In some embodiments, the photovoltaic cells are designed for assembly in a module with electrical connections between a plurality of cells within a module and with appropriate sealing of the module to protect the cells.

In general, the rough area of the cell is determined by the area of the portion of silicon ribbon that comprises the semiconducting core that is use to absorb light and generate the photocurrent, although other components can extend the dimensions of the cell relative to the portion of silicon ribbon. The width of suitable cells generally range from about 1 centimeters (cm) to about 30 cm, in further embodiments from about 2 cm to about 27.5 cm and in additional embodiments form about 2 cm to about 25 cm. The ribbons can be formed in a continuous process so that the length of the portion of ribbon for a single cell can be selected as desired, and the corresponding length of a cell can be correspondingly selected. Specifically, the area of the portion of silicon ribbon results in a particular current for a cell. In some embodiments, the length of a cell can be from about 1 cm to about 200 cm, in further embodiments from about 2 cm to about 150 cm and in additional embodiments from about 5 cm to about 100 cm. A person of ordinary skill in the art will recognize that additional ranges of cell dimensions within the explicit ranges above are contemplated and are within the present disclosure.

The front passivation layer and/or rear passivation layer generally can have texture to scatter light into the semiconductor layer, for example, to increase effective light path and corresponding absorption of the light. In some embodiments, the textured material can comprise a rough surface with an average peak to peak distance from about 50 nm to about 100 microns. The texture can be introduced during the deposition process to form the passivation layer and/or the texture can be added subsequent to the deposition step.

For assembly of cells into a module, it is generally desired to connect a plurality of cell in a series connection to increase the voltage output. For a set of series connected photovoltaic cells, the voltages are additive, and the current output is limited to the lowest value of current generation for the series of cells. To increase energy production for a set of photovoltaic cells, it is desirable for cells connected in series to have similar values of current generation. It has been found that dynamic measurements of the semiconductor properties on the silicon core of a silicon based photovoltaic cell can be used for dynamic selection of cell size. Thus, the specific length can be selected within a particular range based on real time measurements of the semiconducting properties, such as minority carrier lifetimes, such that cell current generation can be more evenly matched. Optical measurements can be made to obtain estimates of minority carrier lifetimes. Optical measurements for dynamic solar cell design are described further in published U.S. patent application 2008/0202577 to Hieslmair, entitled “Dynamic Design of Solar Cell Structures, Photovoltaic Modules and Corresponding Processes,” incorporated herein by reference.

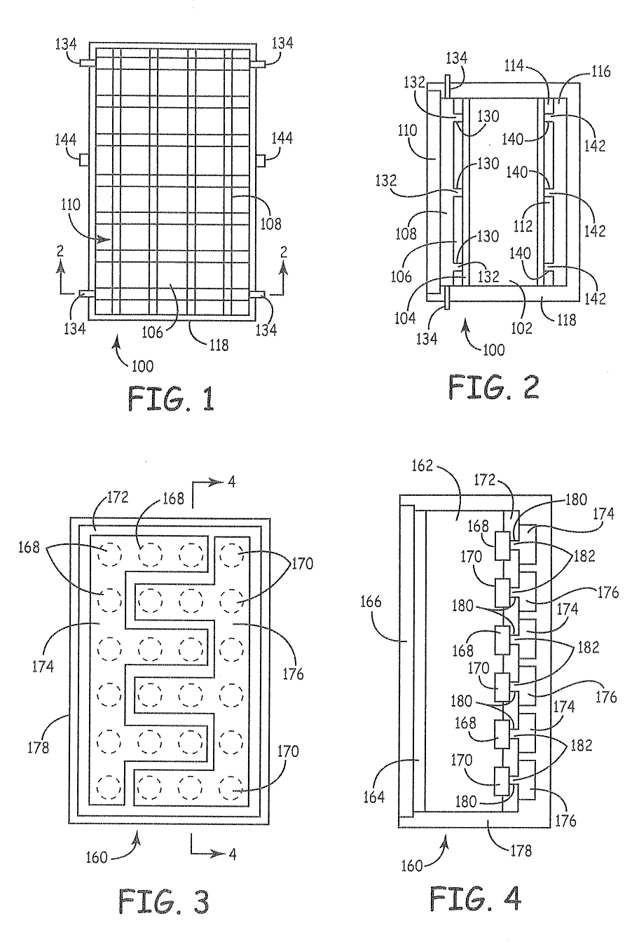

An embodiment of a photovoltaic cell with both front and rear contacts is shown schematically in FIGS. 1 and 2. Referring to FIGS. 1 and 2, photovoltaic cell 100 comprises ribbon silicon 102, a front doped layer 104, a front passivation layer 106, front current collector 108, front protective layer 110, back doped layer 112, back passivation layer 114, back current collector 116 and polymer encapsulant 118. In some embodiments, the ribbon silicon comprises a dopant element at a relatively low dopant level, such as an n-type dopant, to increase the electrical conductivity of the ribbon silicon. In general, the ribbon silicon can have an average dopant concentration of about 1.0×10¹⁴ to about 1.0×10¹⁶ atoms per cubic centimeter (cc) of boron, phosphorous or other similar dopant. A person or ordinary skill in the art will recognize that additional ranges of light dopant levels within the explicit ranges above are contemplated and are within the present disclosure.

Front doped layer 104 and back doped layer 112 can each comprise a selected dopant. In some embodiments, it is desirable for the front doped layer to comprise a p-type dopant and for the back doped layer to comprise an n-type dopant, such that holes formed by the absorption of light migrate to the front surface while electrons migrate to the back surface. The migration of the electrons and holes results in the harvesting of useful current that can be directed to an outside circuit. Suitable n-type dopants include, for example, P, Sb and/or As, and suitable p-type dopants include, for example, B, Al, Ga and/or In. Generally, the average dopant levels on the doped layers can be from about 1.0×10¹⁸ to about 5×10²⁰, in further embodiments 2.5×10¹⁸ to about 1.0×10²⁰ and in other embodiments form 5.0×10¹⁸ to about 5.0×10¹⁹ atoms per cubic centimeter (cc). A person of ordinary skill in the art will recognize that additional ranges of dopant levels within these explicit ranges are contemplated and are within the present disclosure. The dopant profile generally can be a function of the approached used to deliver the dopant, as described further below.

Front passivation layer 106 can comprise an inorganic dielectric material. Suitable inorganic materials to form passivation layers include, for example, stoichiometric and non-stoichiometric silicon oxides, silicon nitrides, and silicon oxynitrides, silicon carbides, silicon carbonitrides, dielectric metal oxides, such as aluminum oxide, dielectric metal nitrides, such as aluminum nitride, metal oxynitrides, combinations thereof or mixtures thereof, with or without hydrogen additions or other transparent dielectric materials. In some embodiments, passivation layers can comprise, for example, SiNₓO_{y}, x≦4/3 and y≦2, silicon oxide (SiO₂), silicon nitride (Si₃N₄), silicon rich oxide (SiOₓ, x<2), or silicon rich nitride (SiNₓ, x<4/3). Holes 130 through front passivation layer 106 provide for electrical contact between front current collector 108 and front doped layer 104.

The passivation layers generally can have a thickness generally from about 10 nanometers (nm) to 800 nm and in further embodiments from 30 nm to 600 nm and in further embodiments from 50 nm to 500 nm. A person of ordinary skill in the art will recognize that additional ranges of thicknesses within the explicit ranges above are contemplated and are within the present disclosure. The passivation layers can protect the semiconductor material from environmental degradation, reduce surface recombination of holes and electrons, and/or provide structural design features, as well as provide anti-reflecting properties for front surfaces. The passivation layer generally is also substantially chemically inert so that the cell is more resistant to any environmental contaminants.

Front current collector 108 can comprise a sheet of transparent conductive material or a patterned grid of electrical conductor that provides for transmission of light past the current collector through the gaps in the electrically conductive material. Front current collector 108 comprises extensions 132 that extend through holes 130 to establish electrical conductivity between front current collector 108 and front doped layer 104. Also, front current collector 108 generally comprises one or more electrically conductive tabs 134 that are designed to provide electrical connections with current collector 108. If encapsulant 118 covers individual cells, tabs 134 generally are configured to extend through encapsulant 118, and if encapsulant 118 is used to enclose a plurality of cells within a module, tabs 134 can be used to connect adjacent cells, for example, in a series or in a parallel connection or to connect to an external circuit. A grid configuration of current collector 108 is depicted in FIG. 1, although other grid patterns can be used as desired. If the current collector comprises a transparent conductive layer, the transparent conductive layer generally covers the surface of the photovoltaic cell roughly uniformly, and a corresponding modification of FIG. 1 follows from this configuration with the grid structure absent.

A transparent front current collector can comprise a transparent conductive metal oxide (TCO). Suitable conductive oxides include, for example, zinc oxide doped with aluminum oxide, indium oxide doped with tin oxide (indium tin oxide, ITO) or fluorine doped tin oxide. In further embodiments, the current collector comprises a grid of electrically conductive material, such as elemental metal or metal alloys. In general, the dimensions of the electrically conductive grid are balanced to provide a desired level of contact with the front doped layer while avoiding an undesirable amount of light blockage. Electrically conductive material of the current collector can block light from reaching the semiconductor material at the locations of the material since the electrically conductive material generally absorbs and/or reflects visible light. The pattern of the electrically conductive grid can be selected for convenient processing.

Front transparent layer 110 can comprise a transparent polymer sheet, a glass sheet, a combination thereof or the like. Suitable polymers include, for example, polycarbonates. Polymer layers can be laminated to the base cell structure as described below. If the front transparent layer also comprises glass, an adhesive, such as silicone adhesives or EVA adhesives (ethylene vinyl acetate polymers/copolymers), can be used to secure the glass to a transparent polymer sheet or directly to the current collector surface.

Back passivation layer 114 can essentially mirror front passivation layer 106, although holes 140 through back passivation layer 114 may or may not have the same configuration and sizes as holes 130 through front passivation layer 106, although the ranges of suitable hole parameters can be equivalent for holes 140 and holes 130. Back passivation layer 114 can comprise equivalent compositions as front passivation layer 106. Similarly, back passivation layer 114 can have thickness over equivalent ranges as for front passivation layer 106.

Back current collector 116 generally can be selected to reflect visible light. Light reflected from back current collector 116 passes back through ribbon silicon 102 where the light can be absorbed by the semiconductor for the generation of additional photocurrent. Back current collector 116 can comprise electrically conductive metal, such as aluminum, although any highly electrically conductive material can be used. Back current collector 116 generally comprises electrically conductive tabs 144 that extend to provide for electrical connection with the current collector. If encapsulant 118 covers individual cells, tabs 144 generally are configured to extend through encapsulant 118, and if encapsulant 118 is used to enclose a plurality of cells within a module, tabs 144 can be used to connect adjacent cells or to make a connection to an external circuit.

A representative embodiment of a back contact photovoltaic cell is shown in FIGS. 3 and 4. Referring to FIGS. 3 and 4, back contact photovoltaic cell 160 comprises ribbon silicon 162, front passivation layer 164, front transparent protective layer 166, back p-doped contacts 168, back n-doped contacts 170, back passivation layer 172, first back current collector 174, second back current collector 176 and encapsulant 178. Ribbon silicon 162 can generally have equivalent characteristics of ribbon silicon 102 discussed above. Front passivation layer 164 can comprise suitable inorganic dielectric materials and dimensions discussed above in the context of dielectric layers 106 and 114. However, in the back contact embodiments, front passivation layer 164 generally does not have holes to provide access to underlying semiconducting material. Also, transparent front protective layer can similarly comprise a polymer, a glass, combinations thereof or the like. Encapsulant 178 can enclose an individual cell or a plurality of cells in a module with appropriate electrical interconnections, as discussed above for encapsulant 118.

The back side of photovoltaic cell 160 has a patterned structure to provide for separate locations for the opposite poles of the cell. Various patterns and structures are known in the art for forming back contacts, and any reasonable back contact structure generally can be used. Some specific structures are discussed in the following based on efficient processes for cell processing. The processes for patterning the back contacts are discussed below in the context of silicon ribbons.

Referring to FIGS. 3 and 4, doped contacts 168, 170 are arranged in a pattern that provides for connection to appropriate current collectors. For back contacts, it is desirable to have a distribution of domains of each dopant type across the surface of the semiconductor so that photocurrent can be efficiently harvested. However, the domains of each dopant type should be patterned to provide for placement of a current collector interfaced appropriately with the respective dopant type. Thus, there is a balance of factors in the placement of the doped domains. Back passivation layer 172 generally comprises holes 180 to provide for contact between the respective current collector and the corresponding doped contact. Doped contacts 168, 170 can extend outward from the back surface ribbon silicon 162, extend into the ribbon silicon without extending outward from the surface of ribbon silicon 162, or both extend into ribbon silicon 162 as well as extend outward from the back surface of ribbon silicon 162, and the structure generally depends on the method used to form the doped contact, as described below.

Current collectors 174, 176 are correspondingly patterned to provide electrodes of opposite polarity for the cell. Thus, first current collector 174 makes contact with p-doped contacts 168 through extensions 182 that pass through holes 180. Similarly, second current collector 176 makes contact with n-doped contacts 170 through corresponding holes 180. Current collectors 174, 176 can be formed from a suitable electrically conductive material, such as elemental metal or alloy. Metal current collectors can also function as reflectors to reflect light that passes through the semiconductor material to strike the current collector. Thus, to reflect more light, it can be desirable for current collectors 174, 176 to cover a large fraction of the surface as long as the current collectors of opposite polarity are spaced sufficiently from each other to avoid shorting the cell.

For a selected design of a photovoltaic cell, the cell and possibly a corresponding module with a plurality of cells can be flexible if the cells and module are formed onto transparent polymer front sheet. The silicon ribbon and various coatings applied to complete the photovoltaic cell can be somewhat flexible due to the thin nature of the ribbon silicon core. It can be desirable to have a flexible photovoltaic cell or module for certain applications.

### Silicon Ribbon Structures and Production

Portions of elemental silicon for processing into photovoltaic cells can be advantageously formed from silicon ribbon. Silicon ribbons are thin silicon sheets pulled from a silicon melt in an essentially continuous process. Silicon ribbons can provide a significant cost saving relative to conventional approaches to silicon wafer formation, where a single ingot of silicon is grown and subsequently cut to form wafers. On the other hand, silicon ribbons are generally produced by passing a pair of filaments or strings through a shallow crucible of molten precursor silicon material to form a thin continuous ribbon. As the strings exit the region of molten silicon, a thin film of silicon spans the space between the strings and rapidly cools to form a substantially planar sheet supported by the strings. Devices can then be formed from the silicon ribbon with a reduced amount of wasted silicon material.

Generally, silicon ribbons can have a wide range of dimensions, based upon the process parameters used in their formation. For example, the width of a silicon ribbon can be varied by adjusting the spacing of the strings as long as the properties of the resulting ribbon are appropriate. Also, the thickness of a silicon ribbon depends at least partially upon the pulling rate (i.e. the rate at which the strings are drawn through the molten silicon precursor material), the temperature of molten silicon precursor material, and the dimensions of the strings. Generally, thicker silicon ribbons can be produced by decreasing the pulling rate, and/or decreasing the temperature of the molten silicon precursor material, and/or increasing the dimension of the strings in the direction perpendicular to the plane of the silicon film. Similarly, thinner silicon ribbons can be produced by increasing the pulling rate, and/or increasing the temperature of the molten silicon precursor material, and/or decreasing the dimension of the strings in the direction perpendicular to the plane of the silicon film.

Furthermore, the thickness of a silicon ribbon can vary across its length and width. In particular, the thickness of a silicon ribbon can be generally narrower in the region about each string (hereinafter “neck region”) and generally thicker in the middle region away from the strings. If the ribbon thickness in the neck region is too thin, however, the silicon ribbon may be too fragile, leading to breakage during ribbon formation and/or during subsequent processing of the ribbon. A method for increasing silicon ribbon thickness, and therefore structural integrity, in the neck region by local cooling with gas jets is described in U.S. Pat. No. 7,780,782 B2 to Huang et al., entitled “Method and Apparatus for Growing a Ribbon Crystal with Localized Cooling,” incorporated herein by reference. A method for increasing silicon ribbon thickness in the neck region by the appropriate selection of string geometry and composition is described in published U.S. Patent application 2009/0061224 A1 to Richardson et al. (“the '224 patent”), entitled “Ribbon Crystal String with Extruded Refractory Material,” incorporated herein by reference.

In general, silicon ribbons desirably have a thickness in some embodiments from about 60 μm to about 1 mm, in further embodiments from about 80 μm to about 750 μm, or in additional embodiments from about 100 μm to about 600 μm. The width of the silicon ribbon can generally range from about 1 centimeters (cm) to about 30 cm, in further embodiments from about 2 cm to about 27.5 cm and in additional embodiments form about 2 cm to about 25 cm. The length of the silicon ribbon generally is large enough to extend from the apparatus generating the silicon ribbon from a melt to a cutting apparatus, which generally can be at least several meters, and can be at least about 15 meter, in some embodiments at least about 20 meters, although for embodiments in which the silicon ribbon is spooled after at least partial processing, the silicon ribbon can be at least about 15 meters and in further embodiments at least about 100 meters in length. A person of ordinary skill in the art will recognize that additional ranges of ribbon dimensions within the explicit ranges above are contemplated and are within the present disclosure.

Specific process parameters for forming silicon ribbons with various dimensions are disclosed in the following references, and teachings from these references can be correspondingly adapted in the apparatuses described herein. The formation of silicon ribbon with a width of 50 mm and a thickness of 120 μm to 1 mm is described in U.S. Pat. No. 4,594,229 to Ciszek et al. (“the '229 patent”), entitled “Apparatus for Melt Growth of Crystalline Semiconductor Sheets,” incorporated herein by reference. The formation of silicon ribbons with a width of up to 50 mm and with a thickness from about 120 μm to about 1 mm is described in published U.S. patent application 2009/0025787 A to Gabor (“the '787 patent”), entitled “Wafer/Ribbon Crystal Method and Apparatus,” incorporated herein by reference. Ribbon wafers with thicknesses from about 150 μm to about 300 μm is described in published U.S. patent application 2009/0159114 A to Williams et al., entitled “Photovoltaic Panel and Cell with Fine Fingers and Method of Manufacturing of the Same,” incorporated herein by reference. Ribbon wafers with a thickness varying from about 60 μm to about 320 μm are described in the '224 patent.

In general, silicon ribbons can comprise polycrystalline silicon, although the crystallite size can be relatively large. Polycrystalline silicon comprises a plurality of crystallites (or “grains”) separated by grain boundaries. The grain boundary density in the silicon ribbon can affect the electrical conductivity of the ribbon as well as the electrical conductivity and photovoltaic efficiency of the photovoltaic elements produced from the silicon ribbon. In particular, increased grain boundary density can result in lowered electrical conductivity and/or photovoltaic efficiency.

The grain boundary density (i.e. distribution of crystallite sizes) of formed silicon ribbons is highly influenced by the process parameters used to form the ribbons. In particular, the pull rate and thermoelastic stress acting on a crystal during growth can affect the grain boundary density within the silicon ribbon. Generally, a slower pull rate and less thermoelastic stress on a forming crystals results in a smaller grain boundary density. The '787 patent describes process parameters for forming silicon ribbon where a substantial majority of crystallites have dimensions for most crystallites that are at least 2 times the electron and hole diffusion length. The '229 patent describes the incorporation of a seed crystal into the ribbon drawing process to form silicon ribbon comprising crystallites as large as 25 mm×25 mm. Advantageously, the rate at which the strings are pulled from the liquid can be about the rate at which the silicon film solidifies. In an alternative and/or additional approach, U.S. Pat. No. 7,651,768 to Richardson et al., entitled “Reduced Wetting String for Ribbon Crystal,” incorporated herein by reference, describes the formation and use of strings with increased wetting angles to promote larger crystallite formation. Thus silicon ribbons can be formed with appropriate electronic properties to provide for desirable ranges of photoconversion efficiencies. In general, the silicon ribbon can be pulled at a rate of at least about 0.05 centimeters per minute (cm/min), in further embodiments from about 0.1 cm/min to about 50 cm/min, in additional embodiments from about 0.2 cm/min to about 40 cm/min and in other embodiments from about 0.4 cm/min to about 25 cm/min. A person of ordinary skill in the art will recognize that additional ranges of pull rate within the explicit ranges above are contemplated and are within the present disclosure.

In general, silicon ribbons may or may not comprise doped silicon, although low dopant levels can be desirable to increase electrical conductivity. N-doped and p-doped silicon ribbons can be formed by drawing the strings through molten n-doped and p-doped precursor silicon material, respectively. Suitable n-type dopants include, for example, P, Sb, and/or As and suitable p-type dopants include, for example, B, Al, Ga and/or In. Desirable dopant concentrations can be from about 1.0×10¹⁸ atoms per cubic centimeter (“cc”) to 5×10²⁰ atoms/cc, or from about 2.5×10¹⁸ atoms/cc to about 1.0×10²⁰ atoms/cc, or from about 5.0×10¹⁸ atoms/cc to about 5.0×10¹⁹ atoms/cc. A method for forming a melt comprising doped silicon by continuous feeding of granular doped silicon material into the crucible is described in U.S. Pat. No. 6,090,199 to Wallace et al., entitled “Continuous Melt Replenishment for Crystal Growth,” incorporated herein by reference.

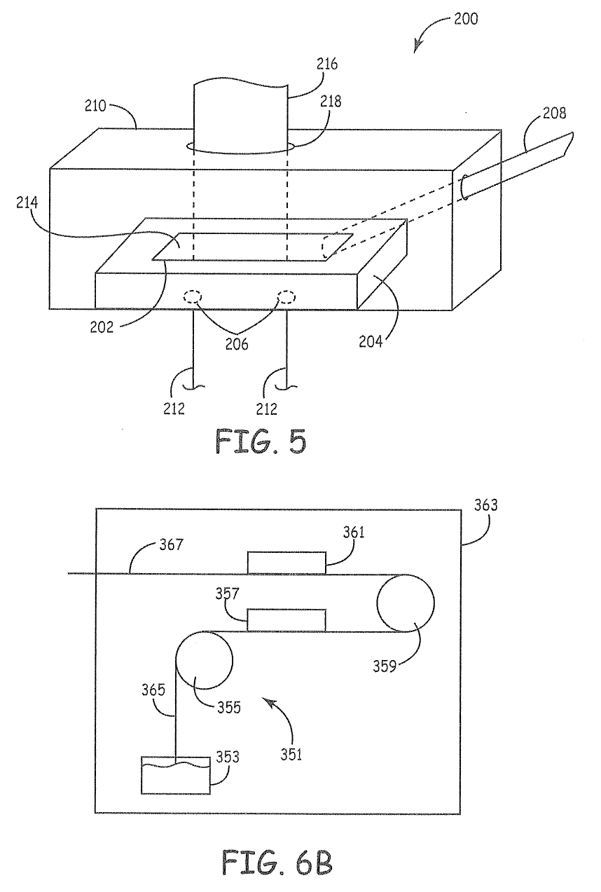

FIG. 5 is a schematic diagram of an embodiment of an apparatus for forming silicon ribbons as described above. Apparatus 200 comprises a crucible 202, a base 204, a plurality of string inlets 206, a feeder system 208, and an enclosure 210. In operation, a substantially inert, oxygen-free atmosphere is provided within enclosure 210, although the entire atmosphere can be enclosed within a larger enclosure that also has a controlled oxygen free atmosphere. Silicon precursor material is then supplied to crucible 202 and is maintained at a temperature above the melting point of the precursor material by base 204 or crucible 202. A pair of strings 212 is then drawn through string inlets 208, through crucible 202, and through a molten silicon precursor material 214. As strings 212 pass through molten silicon reservoir 214, a film of silicon is formed between strings 212 and rapidly cools to form a silicon ribbon 216 which exits enclosure 210 through an exit port 218. A person of ordinary skill in the art will realize that although the embodiment of a silicon ribbon product apparatus depicted in FIG. 5 is directed to production of a single silicon ribbon, such an embodiment can be easily extended to incorporate the simultaneous production of multiple silicon ribbons using ordinary skill in the art. For example, the '787 patent describes pulling a plurality of string pairs, laterally disposed, through a common crucible containing molten silicon. If multiple ribbons are drawn, the discussions of the processing apparatuses below can be correspondingly modified to accommodate the simultaneous processing of the multiple silicon ribbons.

Generally, the crucible 202 can comprise any sufficiently inert material that is heat resistant to a temperature that can maintain the silicon precursor material above its melting point. In some embodiments, it can be desirable to form crucible 202 from a graphitic material that can be resistively heated to maintain the silicon precursor material at a temperature at least above its melting point. In such embodiments, base 204 can comprise an insulating material to increase the heating efficiency of the silicon ribbon production apparatus and/or to reduce any damage from the high temperature crucible. In other embodiments, base 204 can comprise a heating element that maintains crucible 202 and molten silicon precursor material 214 at a temperature at least above the melting point of the silicon precursor material.

Generally, molten silicon precursor material 214 is kept at a temperature that substantially maintains the silicon precursor material in crucible 202 above the melting point of the silicon precursor material. However, the temperature of molten silicon precursor material 214 is selected to be approximately the temperature at which silicon ribbon with desirable properties are formed. For a silicon precursor material comprising non-doped silicon, the temperature of the crucible can be at least about 1415° C., and in further embodiments at least about 1430° C., or at least 1415° C. For a silicon precursor material comprising n-doped or p-doped silicon, the temperature rages can be adjusted to account for changes in the melting point of the doped silicon material due to dopant composition and concentration.

Generally, the physical dimensions of crucible 202 can take any reasonable value, and can be selected with reference to the desired dimensions of the silicon ribbon. The corresponding dimension of crucible 202 can be at least larger than the corresponding dimensions of the desired silicon ribbon. Suitable shapes can include, for example, hemi-spherical or rectangular prismatic geometries.

The composition and dimensions of strings 212 can be advantageously selected to form silicon ribbon with desirable characteristics. Strings 212 can be desirably formed from materials that are wettable by the molten silicon precursor material 214. Suitable materials are described in the '229 patent and can include, for example, graphite, quartz, silicon carbide, silicon nitride or combinations thereof. Furthermore, in order to increase the structural stability of the silicon ribbon in the neck region, it can be desirable to form strings 212 from a single material or a plurality of materials, with a thermal expansion coefficient that is substantially similar to the thermal expansion coefficient of the silicon precursor material. The '224 patent describes a method for forming strings with thermal expansion coefficients and geometries that result in increased stability of the formed silicon ribbon in the neck region, such as silicon carbide and/or silicon nitride.

Feeder system 208 can provide silicon precursor materials to crucible 202 either continuously or in batch operation. Furthermore, in some embodiments, feeder system 208 can provide silicon precursor material comprising molten silicon. In other embodiments, feeder system 208 can provide silicon precursor material comprising silicon granules and/or silicon particles. In yet further embodiments, feeder system 208 can provide silicon precursor material comprising solid silicon in larger dimensions. Generally the rate at which feeder system 208 provides silicon precursor material to crucible 202 can depend upon the form of the silicon precursor material, the temperature of the crucible 202, and/or the draw rate of strings 212. The rate at which feeder system 208 delivers silicon precursor material to crucible 202 can be desirably selected to maintain a sufficient amount of molten silicon precursor material 214, at a sufficient temperature, for production of silicon ribbon 216.

### Direct Processing of Ribbons

Efficient processing of the silicon ribbon can be performed with some of the processing steps directed at the moving ribbon. In some embodiments, the heat of the ribbon can facilitate the processing, and the motion of the ribbon can be adapted for specific process that can take advantage of the motion of the ribbon. Thus, efficient and cost effective process can be performed to make corresponding lower cost photovoltaic cells. The in-motion processing can be adapted for forming photovoltaic cells with front and back contacts or for cells with only back contacts. Specifically, the in-motion process steps can comprise deposition of dopant over a surface, deposition of dielectric material across a surface, deposition of a transparent conductive electrode across a surface, deposition of opaque and/or reflective electrically conductive material, texturing of a surface, lamination of a polymer film, combinations thereof or the like.

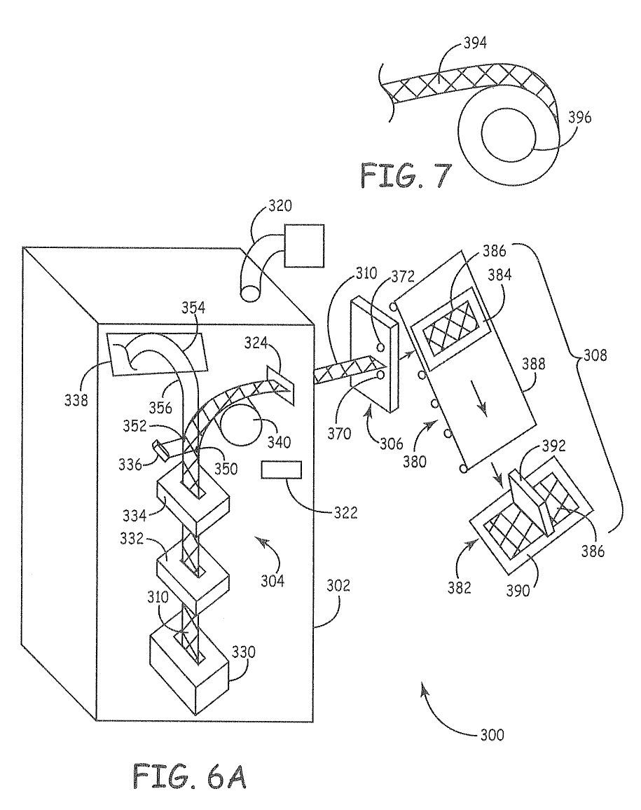

A schematic diagram of an apparatus to perform the processing of photovoltaic cells with one or more in-motion processing steps is shown in FIG. 6A. Processing apparatus 300 comprises an optional insulating enclosure 302, ribbon production and initial or pre-cutting processing section (hereinafter “in-motion processing section”) 304, ribbon cutter 306, and cut ribbon processing and handling section (hereinafter “post-processing section”) 308, which are designed for handling and processing of silicon ribbon 310. Optional insulating enclosure 302 can have an appropriate size to enclose desired sections of the apparatus. Enclosure 302 can also provide a controlled atmosphere so the atmosphere and pressure may not be the ambient gas and/or pressure. Thus, enclosure 302 can comprise a ventilation system 320 that can comprise a pressure control system and/or a gas supply to provide a controlled composition atmosphere. Enclosure 302 can have insulating walls and may or may not comprise one or more heating elements 322, such as a heat lamp or resistance heater, or other thermal control elements. Enclosure 302 can also comprise a slit 324 for exit of silicon ribbon 310. Slit 324 can be configured to reduce exchange of gas between the enclosure and the ambient atmosphere and to help to maintain any pressure differentials and temperature differentials between the interior and exterior of enclosure 302, such as with the inclusion of appropriate baffles or the like. As shown in FIG. 6A, ribbon cutter 306 and post-processing section 308 are positioned outside of enclosure, but in alternative embodiments ribbon cutter 306 and/or post-processing section 308 can be within enclosure 302. If sections of ribbon are cut within enclosure 302, slit 324 can be replaced with an air-lock system or the like to remove cut portions of ribbon.

In-motion processing section 304 can comprise a ribbon silicon production system 330, one or more in-motion processing units (shown as two units 332, 334), string cutter 336, string recycling unit 338, and transport system 340. Ribbon silicon production system 330 comprises a device for the formation of ribbon silicon 310. Characteristics and designs for ribbon silicon production systems 330 are discussed above. In-motion processing units 332, 334 can comprise a deposition unit, a curing or material modification unit or other desired processing device for treating the moving silicon ribbon. A deposition unit can be designed for the deposition of dopant, dielectrics or other desired materials, and suitable deposition units can be configured to deposit a liquid, perform a chemical vapor deposition (CVD) or the like. Deposition units can comprise appropriate mass flow controllers, valves and other control elements, such as those known in the art, to facilitate control of the deposition onto the silicon ribbon. Suitable curing units can be designed to alter the composition and/or properties of the deposited material, and/or to facilitate adherence and/or interaction between the silicon ribbon and deposited materials. Suitable curing units can comprise heaters, radiation emitting devices, rollers to apply texture, to apply heat and/or to apply pressure to the surface of the ribbon, or the like. Rollers to apply texture can have a correspondingly rough surface, and other rollers generally have a smooth surface. Specific in-motion processing units are described further below in the context of specific photovoltaic cell configurations. As shown in FIG. 6A, two in-motion processing units are shown prior to string cutter 336. In additional or alternative embodiments, in-motion processing section 304 can comprise a single in-motion processing unit, three in-motion processing units or more than three in-motion processing units.

As described above, the silicon ribbon generally is pulled from a melt of silicon between two strings of an appropriate material. The strings are generally cut from the ribbons for use of the silicon ribbon in a photovoltaic cell and optionally for reuse of the strings, although in alternative embodiments the strings can be cut with the silicon ribbon. The silicon ribbon can be fairly uniform over most of the width of the silicon ribbon, but the silicon ribbon generally has significant variation near the strings, such that it can be desirable to cut off a relatively small section of the silicon ribbon adjacent to the strings when the strings are cut. Referring to FIG. 6A, string cutter 336 can comprise a first cutter 350 and a second cutter 352 to respectively cut strings 354, 356. String cutters 350, 352 can comprise mechanical cutters, fluid jet cutters and/or radiation based cutters, such as laser cutters. After cutting, strings 354, 356 can be directed to optional string recycling unit 338. Strings 354, 356 can be formed from relatively valuable materials, as described above, so that it is desirable to reuse the strings as long as the strings maintain most of their integrity. The strings can be cleaned prior to reuse, for example, through contact with a silicon etching agent that does not significantly damage the strings. In some embodiments, strings 354, 356 may form a continuous loop so that they return to ribbon silicon system 330. As shown in FIG. 6A, in-motion processing units are placed prior to string cutter 336, and in additional or alternative embodiments a portion or all of the in-motion processing unit(s) can be placed past string cutter 336 with respect to the motion of the silicon ribbon originating from ribbon silicon system 330.

Transport system 340 can comprise one or more elements used to guide silicon ribbon 310. In some embodiments, transport system 340 comprises rollers or the like to guide the direction of the silicon ribbon through the system. Rollers can be designed to control the stresses placed on the ribbon so that the ribbon does not crack or break. For example, a series of rollers can be used to select the angle of deflection at a particular roller and/or the size of the roller can be selected to be larger to avoid excessive bending. The radius of curvature of the ribbon at any position can be controlled to prevent excessive bending. The safe tolerance for the radius of curvature can depend on the ribbon thickness, the crystallite size and possibly other ribbon parameters. Based on particular ribbon properties, the properties of components of transport system 340 can be appropriately selected.

Ribbon cutter 306 can comprise a mechanical cutter, a fluid jet cutter and/or a radiation based cutter, such as a laser cutter. The timing of the cutter generally is rapid so that the ribbon does not move excessively while the ribbon is cut so that the cut is relatively clean and the upstream processing is not significantly affected by the cutting. The appropriate cutter speed can depend on the rate of ribbon motion. Ribbon cutter 306 can comprise a sensor 370 to measure ribbon motion so that the cut is made to form a ribbon portion of a selected length. Suitable motion sensors can be optically based or based on a roller with a rotation sensor or the like to make mechanical measurements of ribbon motion. As noted above, the length of ribbon selected for cutting can be based on measurements of the silicon properties, e.g., the minority carrier diffusion length. Thus, ribbon cutter 306 can further comprise one or more optical sensors 372 to measure minority carrier diffusion lengths so that the length of ribbon cut can be adjusted based on the silicon properties.

Post-processing section 308 can comprise a ribbon portion transport unit 380 and one or more ribbon portion processing unit 382. Ribbon transport unit 380 can comprise a suitable support 384 for a portion of silicon ribbon 386 as well as appropriate conveyor elements 388. Suitable conveyor elements can comprise, for example, rollers, a conveyor belt, shelves conveyed with drive chains or any other suitable conveyor elements, such as those known in the art.

Processing unit 382 can comprise a support platform 390 for ribbon portion 386 and possibly for support 384, and one or more functional elements 392. Functional element 392 can be designed to deposit materials onto ribbon portion 386, apply radiation, perform patterning, and/or perform other desired processing functions. If a plurality of processing functions is performed on a surface of ribbon portion 386, the ribbon portion can be held stationary and the functional elements can be brought to the ribbon portion or the ribbon portion can be moved to appropriate functional elements. If processing functions are performed on both surfaces of a ribbon portion, ribbon portion 386 may be flipped to perform appropriate functions for surface processing. Processing of ribbon portions may or may not be performed in ambient atmosphere.

As shown in FIG. 6A, the in-motion processing is implicitly performed on a vertically aligned silicon ribbon. However, it may be desirable to perform one or more in-motion processing steps on a horizontally aligned silicon ribbon or at an angle that is neither horizontal or vertical. An embodiment to perform in-motion processing steps onto a horizontally aligned ribbon is shown in FIG. 6B. Referring to FIG. 6B, in-motion processing section 351 comprises ribbon silicon production system 353, first redirection conveyor unit 355, one or more first surface in-motion processing units 357, second redirection conveyor unit 359, one or more second surface in-motion process units 361 within an optional enclosure 363 that encloses one or more of the functional units. The in-motion processing units are described further above and below. Silicon ribbon 365 is produced by silicon ribbon production system 353, and processed silicon ribbon 367 is produced after operation of second surface in-motion processing unit 361. Processed silicon ribbon 367 can be cut for formation of individual photovoltaic cells or rolled onto a spindle for later additional processing. Redirection conveyor units 355, 359, 361 are designed to change direction of the silicon ribbon, and these conveyor units can be designed to avoid excessive bending or other stresses on the silicon ribbon. Redirection conveyor units 355, 359, 361 can comprise large rollers made of suitable materials, such as high temperature graphite or ceramics, or these units can comprise a plurality of closely spaced rollers to accomplish an equivalent redirection. Further embodiments can comprise some processing units oriented in a vertical orientation, other processing units in a horizontal orientation, and/or other processing units at an alternative angle.

In alternative embodiments, the processed silicon ribbon does not pass through a cutter. The processed ribbon can then be wound onto a spool for delivery and later processing to complete a desired product. The processed silicon ribbon can comprise one or more coatings or surface modifications on one or both surfaces of a silicon ribbon core. Referring to FIG. 7, processed silicon ribbon 394 can be wound onto spool 396. The inner diameter of spool 396 can be selected to provide sufficient radius of curvature so that the processed silicon ribbon generally is not damaged and does not crack.

With respect to post-processing, processes used for other silicon materials can be adapted to further processing on the back side of the silicon ribbon. The formation of back surface contact following the deposition of a dielectric layer is described further in published U.S. patent application 2008/0202576 to Hieslmair (hereinafter “the '576 application”), entitled “Solar Cell Structures, Photovoltaic Panels and Corresponding Processes,” incorporated herein by reference. A process for the formation of doped contacts along a bare silicon surface prior to dielectric deposition is described in copending U.S. patent application Ser. No. 12/469,441 to Srinivasan et al., entitled “Back Contact Solar Cells With Effective and Efficient Designs and Corresponding Patterning Processes,” incorporated herein by reference. A laser based patterning approach for the placement of current collectors is described further in copending U.S. patent application Ser. No. 12/469,101 to Srinivasan et al., entitled “Metal Patterning for Electrically Conductive Structures Based on Alloy Formation,” incorporated herein by reference.

The various processing components can be thermally insulated and/or cooled, for example, with a cooling fluid, to protect components and reactants from heat within an enclosure and heat from the silicon ribbon. Similarly, components of processing units can be placed exterior to the enclosure to facilitate maintaining the components within desired temperature ranges.

In-Motion Process For Photovoltaic Cells with Front and Back Contacts

For the production of photovoltaic cells with both front and back contacts, doped layers are applied to both surfaces of the silicon ribbon. Thus, some initial process steps can be relatively symmetric with respect to the two surfaces of the silicon, although different dopant types are applied to the respective opposite surfaces and current collectors generally have fundamentally different configurations. In general, the number of process steps can be selected as desired with additional steps being performed following the cutting of the silicon ribbon to form particular portions. In some embodiments, essentially all of the processing steps can be performed in-motion except for inherently cell level processing, such as application of electrical connections between cells or to a lead for connection to an external circuit, incorporation into a module or application of an encapsulant.

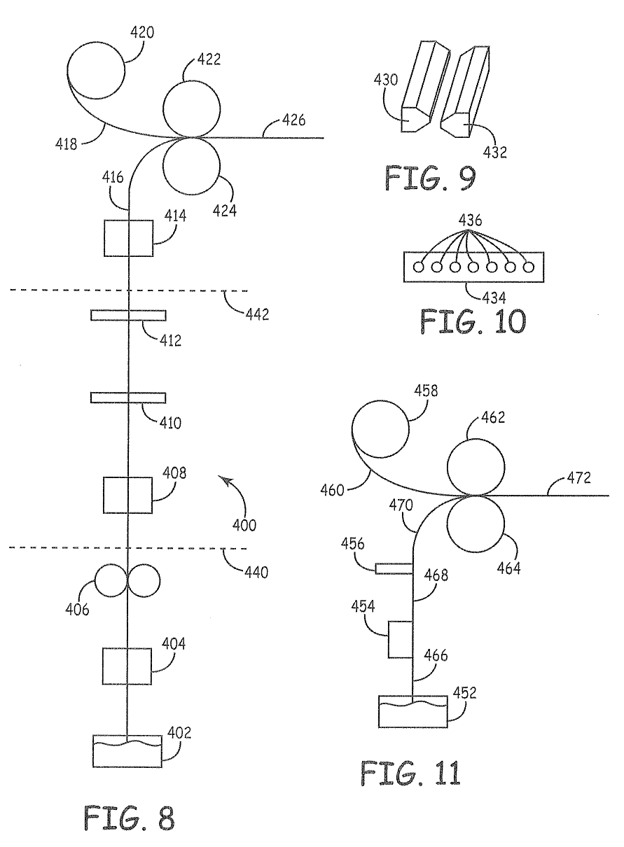

As described above in the context of FIG. 6A, processing steps are divided with respect to placement before or after a ribbon cutter to provide for selected processing on a moving ribbon prior to cutting of the ribbon. A schematic depiction of an embodiment of an in-motion processing section is shown in FIG. 8 for processing related to a photovoltaic cell with front and back contacts. In the embodiment shown in FIG. 8, in-motion processing section 400 can comprise silicon ribbon production system 402, dopant deposition unit 404, dopant drive-in unit 406, dielectric deposition unit 408, dielectric curing unit 410, dielectric hole producer 412, current collector deposition unit 414, which collectively form processed silicon foil 416. A polymer sheet 418 from polymer source 420 can be laminated to processed silicon foil 416 with lamination rolls 422, 424 to form polymer supported silicon cell material 426. The characteristics and operation of apparatus for the production of silicon ribbons are discussed in detail above, which can be adapted for silicon ribbon production system 402. To simplify the discussion, the processing of the two sides of the silicon ribbon is described as being performed through the procession parallel. However, the processing of the two sides can be decoupled as desired such that both sides do not necessarily receive equivalent in-motion processing and the processing of the two sides can be physically displaced. Thus, the particular processing units for the two sides of the ribbon can be physically and/or functionally independent of each other even though they are described as a single unit in the context of FIG. 8, for simplicity.

Dopant deposition unit 404 can be configured to deliver a selected dopant source. Suitable dopant sources can comprise, for example, a liquid, a spin on glass, doped silica particles and/or doped silicon particles. Thus, in some embodiments, the dopant source can be delivered as a liquid, and the dopant deposition unit can comprise suitable nozzles to deliver the liquid to the silicon foil surface. In general, any reasonable nozzle design can be used. If dopant is applied to both sides of the silicon ribbon, appropriate nozzles are correspondingly placed on both sides of the ribbon in the dopant deposition unit 404, although as noted above the doping of the two sides of the ribbon can be physically separated if desired. Respective nozzles can be connected to a suitable dopant liquid reservoir. Referring to FIG. 9, slit nozzles 430, 432 are shown that are configured to deposit a sheet of dopant material as a line on the ribbon that is swept along the ribbon through the ribbon motion. Referring to FIG. 10, an array 434 of circular nozzles 436 is shown that can be positioned to deposit a relatively uniform amount of dopant liquid to the silicon ribbon surface. Other suitable deposition elements, such as slot coaters, extruders, physical vapor deposition elements, chemical vapor deposition elements or the like, or combinations thereof, can be used additionally or alternatively to nozzles shown in FIGS. 9 and 10 for dopant deposition or generally for deposition of desired compositions other than dopants within the processing apparatus.

Suitable liquids for supplying phosphorous dopant include, for example, trioctyl phosphate and/or phosphoric acid in ethylene glycol, and suitable liquids for supplying boron dopant include, for example, boric acid in ethylene glycol and/or propylene glycol. In additional or alternative embodiments, doped silica particles can be used to delivery dopant atoms to the silicon surface. Silica, silicon oxide, can be formed as nanoparticles with a high dopant level for the formation of well disbursed silica inks for the delivery of dopant atoms. The formation of silica inks as a dopant source are described in published U.S. patent application 2008/0160733 to Hieslmair et al., entitled “Silicon/Germanium Oxide Particle Inks, Inkjet Printing and Processes for Doping Semiconductor Substrates,” incorporated herein by reference.

Spin-on glasses can also be used for supplying dopants and can be cost effective. For example, doped spin-on-glasses are available from Desert Silicon (AZ, USA). Spin-on-glass compositions can comprise polysiloxane polymers with dopant elements in a suitable organic solvent, such as an alcohol. Specific formulations are described in U.S. Pat. No. 5,302,198 to Alman, entitled “Coating Solution for Forming Glassy Layers,” incorporated herein by reference. This patent describes the introduction of boron or phosphorous dopants at levels of about 5 to 30 weight percent. Alternative compositions are described in U.S. Pat. No. 7,270,886 to Lee et al., entitled “Spin-On Glass Compositions and Method of Forming Silicon Oxide Layer Semiconductor Manufacturing Process Using the Same,” incorporated herein by reference. The use of spin-on glasses to provide dopants for thin silicon sheets is described further in copending U.S. patent application Ser. No. 12/469,441 to Srinivasan et al., entitled “Back Contact Solar Cells With Effective and Efficient Designs and Corresponding Patterning Processes,” incorporated herein by reference.

Also, doped silicon nanoparticles can be formulated in a well dispersed ink for deposition as a dopant source. The silicon particles can be formed with a high level of dopant. The silicon particles have been successfully formulated into ink jet inks as well as into viscous pastes that are suitable for screen printing. The more viscous formulations can be painted onto the silicon foil. The delivery of silicon particles as a dopant source is described further in published U.S. patent application 2008/0160265 to Hieslmair et al, entitled “Silicon/Germanium Particle Inks, Doped Particles, Printing and Processes for Semiconductor Applications,” incorporated herein by reference.

Generally, heat is applied to drive the dopant into the surfaces of the silicon ribbon to provide a desired degree of dopant penetration into the silicon ribbon. In the configuration of the system shown in FIG. 8, the silicon ribbon can be hot when the dopant source is applied. The heat from the silicon ribbon can drive off solvents, and can poise the material for dopant drive in with the application of some additional heat at the surface. The high temperature of the silicon can significantly facilitate the dopant drive-in since the application of a modest amount of heat at the surface can raise the local surface temperature to the silicon melting point. In this context and generally within an insulating enclose for processing, the initial silicon ribbon temperature can be from about 600° C. to about 1350° C., in further embodiments from about 700° C. to about 1300° C. and in other embodiments from about 750° C. to about 1200° C. A person of ordinary skill in the art will recognize that additional ranges of ribbon temperature within the explicit ranges above are contemplated and are within the present disclosure. The temperature at dopant delivery can be controlled by placement of dopant deposition unit 404 and the cooling rate in the environment surrounding the processing section. It is possible that the latent heat of the silicon ribbon alone can be sufficient to cause diffusion of dopant into the silicon layer to a desired degree, but a dopant drive-in unit can be used to further drive this process.

An optional dopant drive-in unit 406 can be designed to provide additional heat and/or other processing conditions to perform the dopant drive-in. For example, dopant drive-in unit 406 can comprise a heat lamp, such as a xenon heat lamp, a laser with appropriate optics to raster the laser across the surface, or heated rollers or the like to apply conductive heat to the surface. The dopant drive-in for the two separate surfaces of the silicon ribbon may or may not be performed simultaneously. But the processing to drive-in the dopant on a particular side of the ribbon generally involves a processing unit positioned to face the ribbon surface to experience the dopant drive in.

In general UV lasers, infrared lasers, or green lasers may be useful to provide dopant drive-in, although in general the laser energy can be set to a relatively low power level if the temperature of the silicon is high. If the silicon ribbon is hot, a modest amount of heat for a correspondingly modest period of time may be sufficient to provide desired dopant drive-in. In alternative embodiments, after deposition of dopant, the ribbon can be cut and further processing can be performed on the cut ribbon portion, although the discussion herein continues for the description of the performance of additional processing steps in-motion. For additional, in-motion processing the surface can be optionally cleaned or polished after the dopant drive-in is completed, for example using a suitable abrasive roller or contacting the surface with a suitable etchant composition if the ribbon is sufficiently cooled.

After the dopant drive-in, dielectric deposition unit 408 can desirably deposit, in-motion, dielectric material. As noted above, the deposition of dielectric for the respective sides of the silicon ribbon may or may not be performed simultaneously. Suitable inorganic dielectric materials to form a passivation layer are described above.

For the deposition of a silicon oxide based dielectric, an undoped spin-on glass can be deposited. The deposition of spin-on glass through suitable nozzles is described above, and this process can be adapted for the deposition of undoped dielectric precursors for silicon oxide.

In alternative embodiments, dielectric deposition unit 408 can deposit a dielectric material using a reactive deposition process. In principle, suitable oxide coatings can be deposited using a range of deposition processes in-motion, such as atmospheric pressure CVD. However, the initial processing of hot silicon ribbon is performed in an oxygen free atmosphere. Thus, to perform atmospheric pressure CVD deposition of silicon oxide, aluminum oxide or the like, the silicon ribbon can be directed out from an initial enclosure as shown schematically with the optional wall 440 in FIG. 8 into an ambient atmosphere. In some embodiments, it may be desirable to deposit the dielectric in the enclosure, for example, using scanning subatmospheric CVD or light reactive deposition.

Thus, in additional embodiments, dielectric deposition unit 408 can deposit a dielectric material in a substantially oxygen free atmosphere. A nitrogen source, e.g., NH₃, or an oxygen source, e.g., O₂, can be delivered with the reactant flow to provide secondary reactants for the formation of the dielectric material using either subatmospheric pressure CVD or with light reactive deposition. Silane, e.g., SiH₄, Si₂H₆ or the like, can be used as a silicon precursor for the deposition of silicon nitride or silicon oxide. The high ribbon temperature can facilitate the deposition process. Scanning subatmospheric pressure CVD is described in published U.S. patent application 2009/0017292 to Hieslmair et al., entitled “Reactive Flow Deposition and Synthesis of Inorganic Foils,” incorporated herein by reference. Light reactive deposition involves an intense light source, such as an infrared laser, that is oriented to intersect with the reactant flow while not striking the substrate surface, and light reactive deposition is described further in U.S. Pat. Nos. 7,575,784 to Bi et al., entitled “Coating Formation by Reactive Deposition,” and 7,491,431 to Chiruvolu et al., entitled “Dense Coating Formation by Reactive Deposition,” both of thick are incorporated herein by reference. Also, a thermal plasma spray can be used as described in published U.S. patent application 2007/0269612A to Bijker et al., entitled “Method and an Apparatus for Applying a Coating on a Substrate,” incorporated herein by reference. The composition of the dielectric material may or may not be the same as deposited on the two opposite sides of the silicon ribbon.

For some deposition techniques, the dielectric layer should be deposited in appropriate form for use. If a spin-on glass is used or possibly in other deposition techniques, it may be desirable to cure or anneal the as deposited dielectric, which may or may not be performed simultaneously for the two sides of the silicon ribbon. Referring to FIG. 8, optional dielectric curing unit 410 can comprise one or more heat lamps, resistance heaters, heated rollers or the like to provide heat to the as deposited dielectric material or corresponding precursor material, which are positioned at one or both sides of the ribbon as appropriate. After deposition and possible curing/annealing of the dielectric, the silicon ribbon can be cut for further processing. As described in the following, it is possible to perform additional in-motion processing.

After the deposition of the dielectric layer, holes can be placed through the dielectric layer to provide for contact with the underlying doped semiconductor. For example, holes can be drilled through the dielectric, for example, using a laser beam that is appropriately absorbed by the dielectric material, although mechanical drilling can provide an alternative approach. Laser hole drilling can use a green to UV laser can be used, for example, with a short pulse from 10 nanoseconds (ns) to 100 ns, although other laser frequencies and firing sequences can be used. Laser fluences of about 2 to about 30 J/cm² per pulse are estimated to be appropriate for a single pulse to open a hole. A person of ordinary skill in the art will recognize that additional ranges within the explicit laser parameter ranges above are contemplated and are within the present disclosure. Experiments have shown that for a silicon rich silicon nitride film with a thickness of about 60 nm, a single 25 ns pulse at 355 nm wavelength from a wavelength tripled YAG laser formed a suitable opening with a fluence of 4.3 J/cm². Laser hole drilling through a dielectric is described further in the '576 application referenced above. After laser hole drilling, the silicon ribbon optionally can be cut for additional processing, although in the following discussion additional in-motion processing steps are described.

The processing steps for the deposition of the current collector are qualitatively different for the two sides of the silicon ribbon. Specifically, the back side of the silicon ribbon generally can receive an opaque current collector while the front side receives either a transparent conductive electrode or a patterned electrode that allows for the passage of most incident visible light. If desired, the in-motion process can perform the deposition of only a single current collector or for both current collectors. Thus, for example, current collector deposition unit 414 can comprise a component to deposit only the back side current collector, or in further embodiments, the components for depositing the back side current collector and the front side current collector can be physically separated from each other. The deposition of transparent conductive oxides can be performed in an oxygen atmosphere onto a relatively cool silicon ribbon. As shown in FIG. 8, the silicon ribbon can pass through an optional wall 442 prior to deposition of the current collector(s) at current collector deposition unit 414. In some embodiments, the components of the current collector deposition unit 414 for depositing the back side current collector and the front side current collector can be on opposite sides of an enclosure, for example, with a metal coating applied in a low or no oxygen atmosphere on one side and a transparent conductive oxide coating deposited in an oxygen atmosphere.

Current collector deposition unit 414 can comprise a sputtering unit to apply a relatively uniform metal across one side of the silicon ribbon. For example, the component can sputter aluminum onto the ribbon. In alternative embodiments, a metallic silver ink can be deposited. Suitable commercial silver inks include, for example, DowCorning® Brand highly conductive silver inks and conductive silver ink 2512 from Metech, Elverson, Pa. Heat can be applied with radiation or a hot roller to cure a silver ink into an electrically conductive silver layer.

A layer of a transparent conductive oxide can be deposited on the front surface of the ribbon using a reactive deposition approach, such as atmospheric pressure CVD, if performed under ambient atmosphere conditions, or scanning subatmospheric pressure CVD within controlled atmosphere conditions. Atmospheric pressure CVD and scanning subatmospheric pressure CVD are discussed further above.

To form patterned current collectors on the front surface, a silver ink or other metal ink can be printed in the desired pattern onto the ribbon surface. Inkjet nozzles or the like can be mounted to print the ink in the desired pattern onto the ribbon surface as the ribbon passes past the nozzles. The metal ink can then be cured with heat after deposition to form the desired patterned current collector.

In some embodiments, a polymer sheet is laminated to the silicon foil. Polymer sheet 418 can comprise polyethylene, polypropylene, polycarbonate, combinations thereof or the like. The sheet of polymer can be delivered from a roll delivered from spool 420. Polymer sheet 418 and processed silicon ribbon 416 are directed such that they pass face-to-face through lamination rollers 422, 424. Lamination rollers 422, 424 can applied a selected amount of pressure and/or heat to achieve the desired adherence of the layers to form polymer supported silicon cell material 426.

As noted above, the apparatus has been described in the context of FIG. 8 to perform a large number of process steps in-motion, but the ribbon can be cut at an earlier stage in the process with additional process steps performed on a cut portion of ribbon. Also, as noted above, various portions of the in-motion processing can be performed in enclosures with controlled temperatures and/or atmospheres and additional portions of the processing can be performed in separate enclosures or in an ambient atmosphere. while the ribbon is shown in the vertical orientation along the entire path through lamination, the ribbon can be displaced laterally or changed in orientation as desired to facilitate processing and/or facility design using an appropriate conveyor system to manipulate the ribbon essentially according to the production rate of the ribbon. With respect to any processing steps performed on a cut section of silicon ribbon, depositions can be performed through adaption of the in-motion processes described above, or more conventional CVD or physical vapor deposition approaches can be used. The adaptation follows from the description above in view of the cited references that further describe the respective techniques.

In operation, the silicon ribbon originates at the silicon ribbon production system as the strings are pulled through molten silicon. The ribbon solidifies as the strings move away from the crucible, and process can then be performed on the moving ribbon. Movement of the strings can be used to propel the ribbon unless and until the strings are cut from the remaining portion of the silicon ribbon. The transport system moves the strings or the ribbon directly to move the ribbon past the selected processing units in-motion. After the in-motion processing is completed, the ribbon is cut into ribbon portions. In the further discussions below on forming back contact photovoltaic cells, the nature of the deposition units, the precursors and compositions generally are similarly applicable, and the details may not be fully repeated to avoid repetition. Similarly, some optional processing steps may not be described although they may be equally suitable for these other embodiments for equivalent type processing in corresponding placed in the overall process. But it will be understood that the corresponding features in the detailed discussion in this section are equally applicable in the following section.

### Back Contact Cells and Patterning of Doped Contacts and Current Collection

Back contact solar cells have significant structural asymmetries between the front surface and the back surface of the photovoltaic cell that translate into corresponding differences in the process. In some embodiments, the front surface is processed in-motion while the back surface is processed after cutting the silicon ribbon. In other embodiments, one or more processing steps for the back surface are performed in-motion, although the first processing step on the back surface comprises dopant patterning. In the various embodiments relating to back contact photovoltaic cells, significant efficiencies can be introduced through the performance of one or more processing steps in-motion.

In one embodiment of an apparatus shown in FIG. 11, the front surface processing is performed in-motion, and the silicon ribbon is cut for processing of the back surface involving patterning to form the respective contacts. Referring to FIG. 11, an in-motion processing apparatus 450 is designed to process the front surface of the silicon ribbon and laminate a polymer sheet to the ribbon prior to cutting the ribbon. Specifically, in-motion processing apparatus 450 comprises a silicon ribbon production system 452, a dielectric deposition unit 454, a dielectric curing unit 456, a polymer sheet source 458, and lamination rolls 462, 464. In operation, a silicon ribbon 466 is pulled from silicon ribbon production silicon system 452 and past dielectric deposition unit 454. Dielectric deposition unit 454 deposits a dielectric composition onto one surface of silicon ribbon 466. Coated silicon ribbon 468 is subsequently pulled past dielectric curing unit 456, which cures the dielectric coating applied to silicon ribbon 466. Polymer sheet 460, supplied from poly source 458, is then brought in contact with the dielectric coated surface of cured silicon ribbon 470 at lamination rolls 462, 464 to form polymer laminated silicon ribbon 472.

Silicon ribbon production system 452, dielectric deposition unit 454, dielectric curing unit 456, polymer source 458, polymer sheet 460, and lamination rolls 462, 464 can be substantially equivalent to corresponding silicon ribbon production system 200, dielectric deposition unit 408, dielectric curing unit 410, polymer source 420, polymer sheet 418, and lamination rolls 422, 424, respectively. Specifically, dielectric deposition unit 454 can be configured to deposit a spin-on glass or an inorganic dielectric layer using a spray coating, CVD type coating or light reactive deposition process. Dielectric curing unit 456 can apply heat and/or pressure to transform or anneal the dielectric material. Furthermore, although the particular embodiment of an in-motion processing apparatus depicted in FIG. 11 discloses a dielectric curing unit, in some embodiments of a pre-cutting processing apparatus, a dielectric layer can be stably formed without a dielectric curing unit, for example, by direct deposition of a suitable dielectric facilitated by heat form the silicon ribbon.

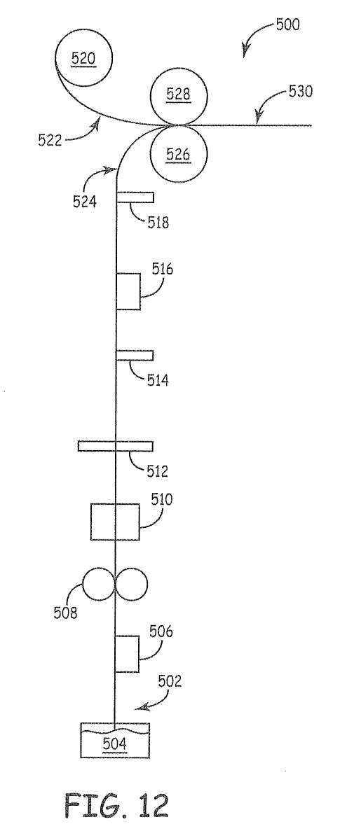

In another embodiment of an in-motion processing section of a silicon ribbon processing apparatus, both front surface processing and back surface processing are performed in-motion to prepare the silicon ribbon for the formation of back contact photovoltaic cells. Referring to FIG. 12, an in-motion processing section 500 is designed to process the front and back surfaces of a silicon ribbon 502, the back surface processing comprising dopant patterning and back contact formation. The front surface of the processed silicon ribbon is ultimately laminated to a polymer sheet. Specifically, the in-motion processing section 500 comprises a silicon ribbon production system 504, a dopant deposition unit 506, dopant drive-in unit 508, dielectric deposition unit 510, dielectric curing unit 512, a dielectric hole generator 514, a current collector pattering unit 516, a current collector curing unit 518, a polymer source unit 520, and lamination rollers 524, 526.

In operation, silicon ribbon 502 is continuously pulled from silicon ribbon production system 504. Doped regions are formed on the back surface of the silicon ribbon by continuously pulling silicon ribbon 502 past dopant deposition unit 506 and dopant drive-in unit 508. Dopant deposition unit 506 deposits, in specific geometries, a n-type dopant source and/or a p-type dopant source on the back surface of silicon ribbon 502. Suitable dopant sources are described in detail above and can be applicable for this embodiment. Similarly, nozzles and the like for deposition of the dopant materials are also described above. Dopant drive-in unit 508 generally applies heat to facilitate the drive in of the dopant elements from the dopant source into the silicon ribbon surface. Heat can be applied with heated rollers, a heat lamp, convective heating, laser heating or other appropriate heat source. Heat from the hot silicon can facilitate the dopant drive in as noted above.

In some embodiments, dopant drive-in unit 508 can comprise heated rollers. The heated rollers can cause at least a portion of the deposited dopant element to diffuse into the surface of the silicon ribbon along the back surface. The heated roller contacting the front surface can comprise a textured heated roller to impart texture to the front surface of silicon ribbon to scatter light impinging on the front surface of the corresponding photovoltaic cell formed form the portion of the silicon ribbon.

Subsequently, dielectric passivation layers are formed on the front surface and/or back surface of doped silicon ribbon 509. A dielectric layer(s) is formed by continuously pulling the silicon ribbon past dielectric deposition unit 510 and dielectric curing unit 512. Dielectric deposition unit 510 deposits dielectric material on the front surface and/or back surface of the silicon ribbon and dielectric curing unit 512 cures the deposited dielectric material generally with the application of heat form a suitable heat source as described further above. As shown in FIG. 12, a dielectric passivation layer is applied simultaneously to the front and rear surfaces of the silicon ribbon. However, the dielectric layers can be independently applied. For example, a front dielectric layer can be applied prior to dopant patterning on the back of the ribbon. As another example, the processing of the front and back surfaces can be independently perform and completed in a selected order. Furthermore, the processing order for the respective steps for the two sides of the silicon ribbon more generally can be selected as desired to effectively design the corresponding apparatus and for the management of heat and other design considerations. Furthermore, in some embodiments of an in-motion processing section, a dielectric layer can be stably formed without a dielectric curing unit, for example by drying at ambient conditions provided in the pre-processing section enclosure (not shown).

Subsequent to formation of the dielectric layer(s), holes can be formed on the back surface of a dielectric coated silicon ribbon to provide for electrical connection to the highly doped contacts on the silicon ribbon surface. The holes can be formed by passing dielectric coated silicon ribbon past dielectric hole generator 514. Dielectric hole generator 514 creates holes through the dielectric layer on the back surface of dielectric coated silicon ribbon. In particular, dielectric hole generator 514 creates holes in a pattern substantially corresponding to the pattern of doped regions created on the back surface of silicon ribbon. More specifically, dielectric hole generator 514 creates a pattern of holes so that each doped region created by dopant deposition unit 504 is at least partially exposed.

Subsequently, current collector deposition unit 516 deposits current collector material on the back surface of dielectric coated silicon ribbon in an appropriate pattern to provide electrical connections between doped regions of the same dopant type. The current collector material can extend through the holes formed in the dielectric to make electrical contact with the doped regions on the silicon surface Current collector deposition unit 516 generally deposits current collector material so that current collector material contacts at least a portion of each doped region on the back surface of doped silicon ribbon. Additionally, current collector deposition unit 516 deposits current collector material such that n-doped regions are all interconnected with current collector material, and such that p-doped regions are all interconnected with current collector material, and such that no current collector material interconnects any n-doped with any p-doped region. Current collector curing unit 518 then can cure the deposited current collector material deposited on the back surface of dielectric coated silicon ribbon to improve the electrical conductivity of the current collector material.

A polymer laminated silicon ribbon 528 is then formed by contacting polymer sheet 522 with processed silicon ribbon 524 and passing the contacted structure through lamination rollers 524, 526. In particular, polymer sheet 522 is provided by polymer source 520 and is contacted with processed silicon ribbon 519. As the contacted structure passes through lamination rollers 524, 526, polymer laminated silicon ribbon 528 is formed.

### Assembly of Photovoltaic Module

Desirably, a photovoltaic module can be formed form individual solar cells. In particular, a plurality of silicon ribbon segments, each comprising a solar cell, can be adjacently spaced and electrically connect to form a photovoltaic module. The spacing can be selected to provide for electrical isolation of adjacent cells while providing for convenient electrical connections and without wasting undesirable amounts of module area. Furthermore, in some embodiments, the silicon ribbon segments can be placed side by side along a transparent substrate. The number of silicon ribbon segments can be selected based on a desired module size and the dimensions of the ribbons. Furthermore, the length of the silicon ribbon segments can be selected to achieve a desired current and/or voltage from the resulting photovoltaic module as well as to account for processing considerations and design parameters of the resulting photovoltaic module. In general, any reasonable length can be used. The ribbon sections can be cut lengthwise and/or widthwise to obtain individual cells of a selected size.

The individual solar cells can be connected in series, or in parallel, or a combination thereof. Where a collection of cells are connected in series, the open circuit voltage of the collection is the sum of the open circuit voltages of the individual cells and the current generated by the collection is limited by the individual cell generating the smallest current. Where a collection of cells are connected in parallel, the current generated by the collection is the sum of the currents generated by the individual cells and the open circuit voltage of the collection is limited by the individual cell having the smallest open circuit voltage. In some embodiments, at least some solar cells are connected in series. Generally, the dimensions of the silicon ribbon segments are selected to produce the desired electrical properties of photovoltaic modules formed therefrom.

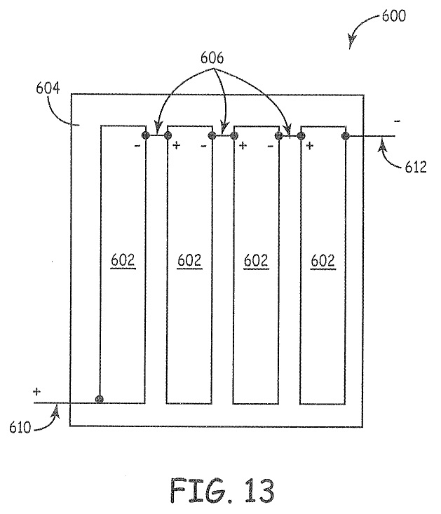

FIG. 13 is a schematic of an embodiment of a photovoltaic module comprising a plurality of silicon ribbon segments connected in series. A photovoltaic module 600 comprises a plurality of silicon ribbon segments 602 adjacently spaced on a transparent substrate 604, such as a glass sheet. Electrical connections 606 provide for electrical contact between current collectors of opposite polarity of adjacent photovoltaic cells to provide for the series connection. External contacts 610, 612 provide for electrical contact with the photovoltaic module, electrical contacts 610, 612 having opposite polarity. In operation, light impinges on the individual solar cells of silicon ribbon segments 602 and current is generated within the individual solar cells. Electrical connections 606 and external contacts 610, 612 allow the current generated in each silicon ribbon segment to be harvested.

The cells can be sealed within modules to provide protection from moisture and other potential environmental contaminants, for example, using known approaching in the art. For example, a polymer encapsulant or a polymer sheet can be placed over the back of the module to protect the photovoltaic cells from moisture and possibly other environmental contaminants. Additional seals or the like can be placed along the edges if desired and appropriate. A module can comprise a frame or the like to provide mechanical support and provide for placement of the module.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein.

What is claimed is:

1. A silicon ribbon processing apparatus comprising:
a silicon ribbon production system comprising a crucible for holding a quantity of molten silicon and strings passing through the crucible to pull a silicon ribbon from the surface of molten silicon within the crucible;
a deposition unit comprising a deposition element positioned to deposit a quantity of composition onto a moving silicon ribbon pulled from the silicon ribbon production system and a quantity of a composition to be deposited onto a surface of the silicon ribbon; and
a silicon ribbon handling system comprising conveying elements positioned to control the movement of the silicon ribbon from the silicon ribbon production unit past the deposition unit.

2. The silicon ribbon processing apparatus of claim 1 wherein the deposition unit comprises a reservoir holding a dopant source and wherein the deposition element comprises a nozzle for the delivery of the dopant source.

3. The silicon ribbon processing apparatus of claim 2 wherein the dopant source comprises a silicon particle ink.

4. The silicon ribbon processing apparatus of claim 1 wherein the deposition unit comprises a p-dopant source, an n-dopant source, a first nozzle to deliver the p-dopant to a first side of the silicon ribbon and a second nozzle to deliver n-dopant to a second side opposite the first side of the silicon ribbon.

5. The silicon ribbon processing apparatus of claim 1 wherein the deposition unit comprises a p-dopant source and an n-dopant source and nozzles configured to pattern the p-dopant and the n-dopant along the same side of silicon ribbon.

6. The silicon ribbon processing apparatus of claim 1 wherein the deposition unit comprises a CVD system connected to precursor reservoirs for the deposition of an inorganic dielectric material.

7. The silicon ribbon processing apparatus of claim 6 wherein the CVD system comprises a silane source and an ammonia source such that the CVD system deposits a layer of silicon nitride.

8. The silicon ribbon processing apparatus of claim 6 further comprising a polymer sheet dispenser and lamination system configured for laminating the polymer sheet over the inorganic dielectric material.

9. The silicon ribbon processing apparatus of claim 1 wherein the deposition unit comprises a source for elemental metal deposition.

10. A method for the formation of a passivation layer on a silicon sheet, the method comprising:
depositing a dielectric material or a dielectric precursor material onto a moving silicon ribbon having an average width from about 1 cm to about 30 cm, an average thickness from about 60 microns to about 750 microns, the silicon ribbon having a temperature from about 600° C. to about 1350° C.

11. The method of claim 10 wherein the dielectric material or the dielectric precursor material comprises a dielectric precursor material comprising a spin-on glass.

12. The method of claim 10 wherein the dielectric material or the dielectric precursor material comprises a dielectric material and wherein the depositing comprises a CVD process wherein the precursor compositions are directed through a nozzle toward the silicon ribbon.

13. The method of claim 10 wherein the silicon ribbon is moving at a rate from about 0.1 centimeters per minute (cm/min) to about 50 cm/min.

14. A method for forming a highly doped surface layer on a silicon sheet, the method comprising:
depositing a first dopant material comprising doped silicon particles or a dopant source precursor onto a surface of a moving silicon ribbon to form a first coated surface, the silicon ribbon having an average width from about 1 cm to about 30 cm, an average thickness from about 60 microns to about 750 microns, to form a dopant coating; and
curing the dopant coating to form a highly doped silicon surface layer.

15. The method of claim 14 wherein the first dopant material comprises doped silicon particles and wherein the curing comprises passing a heated roller over the coated surface.

16. The method of claim 14 wherein the first dopant material comprises a doped spin-on glass and wherein the curing comprises irradiation with a heat lamp.

17. The method of claim 14 wherein the first coated surface comprises a p-type dopant element and further comprising depositing a second dopant material for form a second coated surface on the silicon ribbon opposite the first coated surface, wherein the second dopant material comprises a n-type dopant.

18. The method of claim 14 depositing a second dopant material such that the first coated material and the second coated material form a selected pattern on the first coated surface.

19. A method for forming a protective polymer layer on a silicon sheet, the method comprising laminating a polymer sheet onto a moving front surface of a silicon ribbon an average width from about 1 cm to about 30 cm, an average thickness from about 60 microns to about 750 microns.

20. The method of claim 19 wherein the polymer sheet comprises polycarbonate.

21. The method of claim 19 wherein the laminating step comprises passing the polymer sheet and silicon ribbon together through rollers.

22. A ribbon material comprising a doped silicon ribbon and an inorganic dielectric coating on a surface of the silicon ribbon, the ribbon material having a length of at least about 15 meters, an average width from about 1 cm to about 30 cm, an average thickness from about 60 microns to about 750 microns and a dopant concentration from about 1.0×10¹⁸ to about 5×10²⁰ dopant atoms per cubic centimeter and the inorganic dielectric coating having an average thickness from about 10 nm to 800 nm.

23. The ribbon material of claim 22 wherein the ribbon material has a length of at least about 25 meters and is wound on a spool.
